(19) United States
(12) Patent Application Publication
(10) Pub. No.: US 2018/0145682 A1
(43) Pub. Date: May 24, 2018

(54) POSITIVE AND NEGATIVE DC-DC CONVERTER FOR BIASING RF CIRCUITS

(71) Applicant: MACOM Technology Solutions Holdings, Inc., Lowell, MA (US)

(72) Inventors: Brendan Foley, Co. Wexford (IE); Cristiano Bazzani, Irvine, CA (US); Michelle Dowling, Cork (IE)

(73) Assignee: MACOM Technology Solutions Holdings, Inc., Lowell, MA (US)

(21) Appl. No.: 15/356,355

(22) Filed: Nov. 18, 2016

(51) Int. Cl. H03K 17/567; G05F 1/56; H02M 3/158; H03K 17/284

(52) U.S. Cl. CPC H03K 17/567; G05F 1/56; H01L 29/868; H03K 17/284; H02M 3/158

(57) ABSTRACT

A multi-voltage converter is described that includes multiple programmable bias voltages of positive and negative values that may be used to bias radio-frequency components such as PIN diodes and gallium-nitride devices. Programmable voltages as high as 30 volts and as low as −20 volts are generated. Outputs may be provided to a sequencing circuit for biasing gallium-nitride transistors and amplifiers.

### BACKGROUND

### Technical Field

The technology relates to a multi-voltage converter that may be used for biasing radio-frequency components, such as gallium-nitride devices and PIN diodes.

### Discussion of the Related Art

Radio-frequency (RF) applications, such as wireless communications and radar, often involve the use of electronic components that require one or more bias voltage values that differ from voltages used for supplying conventional logic circuits. Examples of such electronic components include “PIN” diodes and gallium-nitride devices. PIN diodes are semiconductor diodes with wide, intrinsic semiconductor regions between p-type and n-type semiconductor regions on either side of the diode junction. PIN diodes can be used in radio-frequency (RF) applications as switches and/or attenuators, and may be used in some applications as photodetectors and photovoltaic cells. When a PIN diode is forward biased, the PIN diode becomes conductive and can readily pass an RF signal. Under forward bias, the PIN diode essentially appears as a short. When at zero bias or reverse bias, a PIN diode is mainly a capacitive element, since the intrinsic region of the diode is depleted of carriers, and may effectively block an RF signal. For improved isolation, high reverse-bias voltages (10 volts or more) may be used. The capacitance of a PIN diode can be small (e.g., on the order of 1 pF or less). Because a PIN diode has small capacitance, it can be switched at high speed between conductive and capacitive states which makes it attractive for RF applications.

Gallium-nitride (GaN) devices may include GaN transistors, such as high-electron mobility transistors (HEMTs), formed from gallium-nitride material and configured in an amplifier circuit. These amplifiers are useful for RF communications and radar applications because of their high-speed and high-breakdown-voltage capabilities. Gallium-nitride transistors may be biased at their gate with negative voltages as high as −20 volts in some cases (e.g., to prevent conduction) and also supplied at their drain with high positive voltages. In some cases, a GaN device may require appreciable current levels (e.g., more than 20 mA) at negative bias values.

### SUMMARY

Circuits and methods for a programmable, multi-voltage converter that is useful for biasing RF components are described. According to some embodiments, a multi-voltage converter may use only a single low-voltage supply (e.g., a 5-volt supply) and provide multiple, programmable voltage outputs as high as 35 volts and as low as −20 volts and driving currents up to 80 mA. As such, the converter may directly drive circuitry for PIN diodes and/or GaN devices using only a single low-voltage supply. The multi-voltage converter may include an externally programmable register for adjusting converted voltages, so that converted output voltages can be readily tailored to a specific application. Additionally, converted output voltages may be tuned on-the-fly or at set-up to improve performance of components biased by the converter.

Some embodiments relate to a voltage converter comprising a substrate on which the voltage converter is assembled, a supply voltage contact configured to receive electrical power from a power source having a positive voltage, a boost converter connected to the supply voltage contact and configured to convert a first voltage received from the power source to a second voltage that is greater than the first voltage, to a third voltage that is greater than the first voltage, and to a negative voltage. A voltage converter may further comprise a low-dropout regulator configured to convert the second voltage to a fourth voltage, and a register configured to output a first control signal that sets at least the fourth voltage within a positive voltage range that is greater than zero volts.

In some implementations, the boost converter may be configured to output up to 80 mA for the fourth voltage and/or the negative voltage. In some aspects, the supply voltage contact may be the only contact for receiving power that powers the voltage converter. According to some implementations, the register is programmable and is configured to receive a digital signal via a programming contact on the substrate and alter a value of the first control signal responsive to the received digital signal.

In some aspects, the register is further configured to output a second control signal that alters the negative voltage within a negative voltage range. The negative voltage range may extend from approximately −8 volts to approximately −20 volts. The positive voltage range may extend from approximately 15 volts to approximately 28 volts.

According to some implementations, the boost converter may comprise two transistors, two inductor contacts on the substrate that are connected to the two transistors, and switching circuitry configured to switch current through an inductor that attaches to the two inductor contacts. An input of the low-dropout regulator may be arranged to connect to a cathode of a diode having an anode that connects to the inductor.

In some aspects, the first voltage is between approximately 2.5 volts and approximately 7 volts.

According to some implementations, a voltage converter may further comprise a bias driver configured to receive a supply voltage from the low-dropout regulator and switch an output bias voltage between two levels. The voltage converter may further comprise a TTL buffer configured to receive commands via a bias-control contact and activate or deactivate the bias driver.

In some implementations, the bias driver may comprise a first transistor having a drain connected to receive an output voltage from the low-dropout regulator, a first buffer configured to receive power from the low-dropout regulator, to be referenced to a reference voltage that is less than a voltage from the low-dropout regulator and greater than zero volts, and to drive a gate of the first transistor, a second transistor having a drain connected to a source of the first transistor, and a second buffer configured to drive a gate of the second transistor.

In some implementations, a voltage converter may be configured to apply the fourth voltage and the negative voltage to a radio-frequency component. The radio-frequency component may comprise a gallium-nitride transistor.

Some embodiments relate to a method for biasing radio-frequency components with a multi-voltage converter. A method embodiment may comprise acts of receiving, at the multi-voltage converter assembled on a substrate, a first supply voltage; converting, with a boost converter assembled on the substrate, the first supply voltage to a second voltage that is positive and greater than the first voltage; converting, with the boost converter, the first supply voltage to a negative voltage that is less than the first voltage; reducing, with a low-dropout regulator assembled on the substrate, the second voltage to a third voltage; and providing the third voltage and the negative voltage to bias a radio-frequency component.

In some aspects, between about 45 mA and 80 mA of current is provided for the third voltage. The first supply voltage may be the only supply voltage received by the voltage converter.

In some implementations, a method may further comprise acts of receiving, at a programmable register assembled on the substrate, a digital signal, and providing, in response to receiving the digital signal, a control signal from the programmable register that alters the third voltage from a first value to a second value within a positive voltage range that is greater than zero volts.

In some implementations, converting the first supply voltage to the second voltage and converting the first supply voltage to the negative voltage comprises switching two transistors to drive current through a single inductor. The switching may comprise a combination of pulse width modulation and pulse frequency modulation. In some aspects, the first supply voltage may have a value between approximately 2.5 volts and approximately 7 volts and the second voltage may have a value between approximately 20 volts and approximately 35 volts. The negative voltage may have a value between approximately −8 volts and approximately −20 volts.

In some implementations, a method for biasing RF components may further comprise acts of providing the third voltage and the negative voltage to a sequencing circuit, and controlling, with the sequencing circuit, the application of the third voltage and the negative voltage to the radio-frequency component. The radio-frequency component may comprise a gallium-nitride transistor.

The foregoing apparatus and method embodiments may be implemented with any suitable combination of aspects, features, and acts described above or in further detail below. These and other aspects, embodiments, and features of the present teachings can be more fully understood from the following description in conjunction with the accompanying drawings.

### BRIEF DESCRIPTION OF THE DRAWINGS

The skilled artisan will understand that the figures, described herein, are for illustration purposes only. It is to be understood that in some instances various aspects of the embodiments may be shown exaggerated or enlarged to facilitate an understanding of the embodiments. The drawings are not necessarily to scale, emphasis instead being placed upon illustrating the principles of the teachings. In the drawings, like reference characters generally refer to like features, functionally similar and/or structurally similar elements throughout the various figures. Where the drawings relate to microfabricated circuits, only one device and/or circuit may be shown to simplify the drawings. In practice, a large number of devices or circuits may be fabricated in parallel across a large area of a substrate or entire substrate, for example. Additionally, a depicted device or circuit may be integrated within a larger circuit.

When referring to the drawings in the following detailed description, spatial references “top,” “bottom,” “upper,” “lower,” “vertical,” “horizontal,” “above,” “below” and the like may be used. Such references are used for teaching purposes, and are not intended as absolute references for embodied devices. An embodied device may be oriented spatially in any suitable manner that may be different from the orientations shown in the drawings. The drawings are not intended to limit the scope of the present teachings in any way.

FIG. 1 depicts a programmable, multi-voltage converter which may be assembled into a module powered by a single, low-voltage supply, according to some embodiments;

FIG. 2 depicts components of a bias driver, according to some embodiments;

FIG. 3, depicts components of a switch control circuit for a single-inductor boost converter, according to some embodiments; and

FIG. 4 illustrates how a multi-voltage converter may be used to bias a radio-frequency component.

Features and advantages of the illustrated embodiments will become more apparent from the detailed description set forth below when taken in conjunction with the drawings.

### DETAILED DESCRIPTION

The inventors have recognized and appreciated that microwave and radio frequency (RF) systems, such as mobile phone and radar systems, can include circuit components requiring a number of different bias voltage levels with some biasing applications requiring appreciable current levels (e.g., greater than about 20 mA). For example, mobile communication systems may include digital logic circuitry for signal processing and also include analog circuitry for transmitting and receiving RF signals. The digital logic circuitry may require a first set of supply voltages (e.g., one or more of 1.8 volts, 3.3 volts, and 5 volts). The analog circuitry may require large negative voltage values as well as large positive voltage values for switching RF signals (such as in time-division duplex (TDD) communication systems) and for signal amplification (e.g., to transmit signals wirelessly over large distances).

One way to switch RF signals is to use PIN diodes in a branching circuit and bias the PIN diodes appropriately to either pass or block RF transmission on each branch. The inventors have recognized and appreciated that bias voltages required for such PIN diode switches (typically more than 15 volts) is appreciably higher than voltages needed for other electronic components (e.g., buffers, logic chips, ASICs, analog-to-digital and digital-to-analog converters, processors, etc.) of signal processing circuitry in mobile phones and RF systems. This difference in required voltage can present an inconvenience for manufacturers. For example, an additional voltage supply is needed in the system to operate the PIN diodes. It is typically the responsibility of the manufacturer to provide the additional voltage supply or supplies needed for the PIN diodes and driving circuits.

Although GaN devices have emerged as desirable components for RF communication systems and radar applications, they can require multiple voltage supplies and require careful biasing techniques to avoid damaging the devices. For example, it may be necessary upon power-up to reverse bias a gate of a gallium-nitride HEMT with a high negative voltage prior to and while applying a positive supply voltage to a drain of the transistor. The negative bias can prevent an otherwise large current flow that would occur and that could damage the HEMT if the supply voltage alone were applied to the HEMT. In some cases, the negative voltage bias can be as large as −8 volts or more, and the positive voltage bias can be as large as 20 volts or more.

In addition to the large voltages of opposite polarity required in RF and radar applications, sufficient current driving capability may also be needed. For example, PIN diode switches and GaN amplifiers may require supply or bias currents between about 45 mA and about 80 mA to achieve fast switching speeds or large gain values necessary for RF communications. One conventional approach to negative voltage conversion is to use charge-pump type inverters to generate negative voltages. However, these devices are typically limited to current levels of about 10 mA when integrated in a package, and therefore are not useful for providing higher currents to RF components such as high-power, GaN transistors.

To avoid the inconvenience of additional power supplies, the inventors have conceived of a multi-voltage converter that includes a DC-DC boost converter with multiple output voltages, at least some of which are regulated by low dropout regulators (LDOs). The converted output voltages may be capable of providing up to about 80 mA of drive current. In some embodiments, a negative voltage and a positive voltage output from the boost converter may be used to bias GaN devices, such as GaN transistors or GaN amplifiers. In some implementations, voltage levels of the output voltages may be externally and dynamically programmable, so that the output voltages can be tuned to improve performance of components biased by the output voltages. According to some embodiments, the multi-voltage converter can be assembled on a same substrate in a single module that is powered by a single, low-voltage source (e.g., a 5-volt source). Additional components, such as bias drivers and TTL buffers, may be assembled on the same substrate and powered by the same low-voltage source.

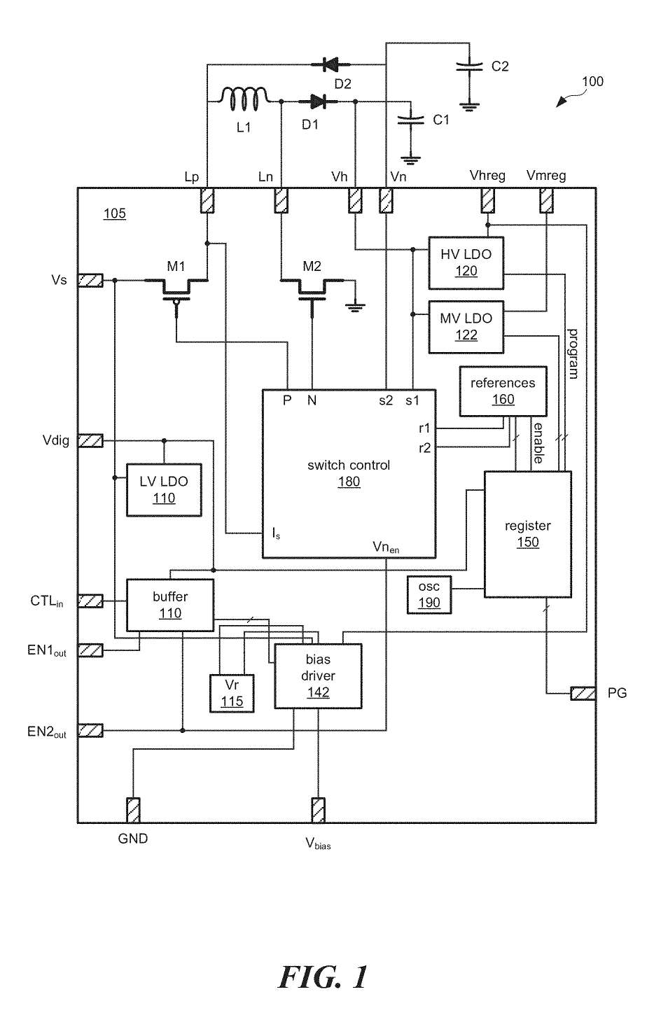

FIG. 1 shows one example of programmable multi-voltage converter 100 for biasing RF and microwave devices. Most of the components for the multi-voltage converter, except for a few external passive components (e.g., inductors, capacitors, diodes, resistors), may be incorporated in a single module in some embodiments. The components may be assembled onto a substrate 105 and incorporated into a ceramic or plastic package having multiple contacts on an external surface. The contacts (e.g., pins, tabs, bumps, or pads) may be designed for making separate connections to the multi-voltage converter within a larger circuit or system (e.g., for inserting into a printed circuit board and/or for connecting with solder). The substrate 105 may be any suitable insulating substrate (e.g., formed from printed circuit board material, plastic, or a ceramic) and may include a ground plane or ground conductors.

In overview, the multi-voltage converter 100 may include a supply voltage contact (labeled “Vs” in the drawing) to which power may be applied to activate the converter and other components integrated on the substrate. In some embodiments, the multi-voltage converter may be powered with a single source (not shown) that outputs a voltage Vₛ between about 2.5 volts and about 7 volts and is capable of providing between about 1 amp and about 6 amps. In some embodiments, the single source may output a voltage Vₛ between about 2.5 volts and about 7 volts and provide between about 0.1 amp and about 1 amp. In some embodiments, the supply voltage contact Vs may connect to a DC-DC boost converter that converts the received low voltage Vₛ to a first high voltage Vₕ (e.g., between about 20 volts and about 35 volts) that is provided to a high-voltage contact Vh. The boost converter may additionally convert the received low voltage to a negative voltage Vₙ, e.g., between about −8 volts and about −20 volts, that is provided to a negative-voltage contact Vn.

The high-voltage Vₕ output from the voltage converter may be provided to a high-voltage, low-dropout regulator (HV LDO) 120, according to some embodiments, which regulates the high voltage down to a second high-voltage value Vh_{reg}. The regulated voltage may be a value between about 15 volts and about 28 volts. The high-voltage Vₕ output from the voltage converter may also be provided to a mid-voltage, low-dropout regulator (MV LDO) 122, according to some embodiments, which regulates the high voltage down to a mid-voltage value Vm_{reg}. The regulated mid-voltage may be a value between about 8 volts and about 11 volts. In some implementations, the regulated voltage from the HV LDO 120 may be provided to a bias driver 142, which may be controlled by signals from a transistor-transistor logic (TTL) buffer 110. In some implementations, the bias driver may be controlled to apply a regulated bias voltage to one or more PIN diodes for switching RF signals and/or to one or more GaN devices.

In further detail, a multi-voltage converter 100 may comprise a DC-DC boost converter that uses a single inductor L1 and provides multiple output voltages, though other types of voltage converters may be used in other embodiments. The inductor may mount external to the package and connect to inductor contacts Lp and Ln. The boost converter may comprise two or more transistors within the package that are configured to switch current from the supply voltage contact Vs through the inductor L1. In some embodiments, there may be two transistors M1, M2 of opposite type (p-FET, n-FET) connected to switch current through the inductor L1. The transistors may be sized to switch up to 2 amps of current through the inductor, and have breakdown voltages as high as 100 volts.

The switching of the transistors M1, M2 may be controlled by a switch control circuit 180. In some implementations, the switch control 180 may comprise circuitry used for single-inductor multiple output (SIMO) converters. The switch control 180 may include two output contacts (P, N) that connect to gates of the transistors M1, M2, and also include a current-sensing contact Iₛ that connects to a source or drain of one of the transistors M1, couples to an end of the inductor L1, and connects to current limiting circuitry with the switch control 180. In some implementations, the switch control 180 may include a negative-voltage enable output contact Vnₑₙ which provides a signal that indicates whether the negative voltage Vₙ has reached a predetermined level.

Additional components for voltage conversion may include two diodes D1, D2 and two charging capacitors C1, C2, which may be mounted external to the package and connect to boost-converter circuitry within the package via a high-voltage contact Vh and a negative-voltage contact Vn, as indicated in FIG. 1. The diodes may also connect to the external inductor L1. These diodes and capacitors may be sized to handle up to 2 amps of current flow that is switched through the inductor L1, and may have high breakdown voltages (e.g., 100 volts or more). By choosing transistors M1, M2, diodes D1, D2, and capacitors C1, C2 to handle large current flows through the inductor L1 and to sustain high voltages (which can be due to voltage spikes resulting from transistor switching) and by using a voltage-conversion scheme that implements both pulse-width and pulse-frequency modulation, the multi-voltage converter may output driving currents up to 80 mA.

In some implementations, the multi-voltage converter may output driving currents between about 45 mA and about 80 mA. The capability of outputting drive currents in this range allows the multi-voltage converter to directly power RF amplifiers that can be used in mobile communication systems (e.g., amplifiers used in cell phones and portable computing devices). It also allows the multi-voltage converter to directly bias PIN diodes at high switching speeds used in mobile communication systems.

The high-voltage contact Vh may be configured to connect to a node between a cathode of the first diode D1 and the first capacitor C1, and may also connect to a high-voltage sensing node s1 of the switch control 180. The negative-voltage contact Vn may be configured to connect to a node between an anode of the second diode D2 and the second capacitor C2, and may further connect to a negative-voltage sensing node s2 of the switch control 180. Circuitry within the switch control 180 may monitor the voltages on the capacitors C1, C2 as they are charged and discharged by the switching of transistors M1, M2, and control switch timing based in part on the detected voltages. One or more contacts r1, r2 may be included with the switch control 180 to receive programmable reference voltage values that can be compared against sensed voltage values, and used to maintain output voltages from the voltage converter at desired levels and/or alter the output voltages to desired levels.

According to some embodiments, reference voltage values for the switch control 180 may be provided by programmable reference circuitry 160. Any suitable voltage reference circuit may be used to provide one or more DC voltage reference values. In some implementations, digital-to-analog converters (DACs) may be included to obtain reference voltage values, where a digital code is applied to obtain a desired analog output reference voltage. Other examples of voltage reference circuits include Zener diode voltage reference circuits, resistive voltage dividers, and programmable bandgap voltage references. According to some embodiments, voltage reference circuits in the reference circuitry 160 may be programmed and/or activated by voltage-programming signals that are transmitted from a register 150. The register may be included in the same package and assembled on the same substrate 105 as the boost converter. Voltage-programming signals may be transmitted upon start-up and/or while the multi-voltage converter is in operation. In some embodiments, voltage reference circuits in the reference circuitry 160 may be programmed directly via external data signals that are provided to the reference circuitry 160.

In some embodiments, multi-voltage converter 100 may include a programmable HV LDO 120 and/or a programmable MV LDO 122 that receive the converted high voltage Vₕ (e.g., voltage appearing at C1) of the boost converter. According to some implementations, an LDO may be programmed by providing a programmable reference voltage, used by the LDO, from the register 150. The inventors have recognized and appreciated that the converted high voltage Vₕ has spikes that result from the switching of transistors M1, M2. These spikes, if passed to the bias driver 142 or external RF components may couple onto and add noise to RF signals that are switched by PIN diodes or amplified by GaN amplifiers, for example. This noise generated by switching of the transistors M1, M2 can degrade RF communication signals.

To reduce the switching noise, the boost voltage converter may convert the input voltage Vₛ to a voltage higher than necessary. The LDOs 120, 122 may then substantially remove the spikes and provide a regulated voltage at lower, desired voltage levels that are suitable for biasing RF components. According to one embodiment, the boost voltage converter may boost the input supply voltage Vₛ from a value between about 2.5 volts and about 7 volts, to about 24 volts, and the HV LDO 120 may regulate the voltage to about 19.5 volts while substantially removing switching noise from the boost converter. Other voltage values may be used in other embodiments.

According to some implementations, the HV LDO 120 and MV LDO 122 may be programmed with digital data received from the register 150, while in other embodiments the LDOs may be programmed with signals received from reference circuitry 160. In some embodiments, the HV LDO may include a DAC that converts the digital signal to an analog signal for use as a reference voltage. In some cases, reference circuitry 160 may output a programmed analog voltage value instead of a digital signal to the LDOs 120, 122 to use as reference voltages. An on-board oscillator 190 may be assembled on the substrate 105 (or a clock signal may be received from an external source) and used to clock data to and from the register 150 upon start-up and during operation.

In the drawings, interconnects having a slash indicate digital data lines having more than one bit per digital word, according to one preferred embodiment. Other embodiments may use analog lines instead of digital lines and vice versa, wherein analog-to-digital and digital-to-analog conversion may be used on the links.

According to some embodiments, the register 150 may be configured on-the-fly, prior to, or at start-up of the multi-voltage converter 100 via a programming contact PG. For example, digital data may be provided to the register 150 via the programming contact to alter voltage reference values provided to the LDOs 120, 122 and/or provided by reference circuits 160. In this manner, voltages Vₕ, Vₙ, Vh_{reg}, and Vm_{reg} may be programmed to desired non-zero values for a particular application. For example, a first set of voltages may be used for a PIN diode switching application, and a second set of voltages may be used for biasing a GaN amplifier. In some implementations, Vₕ may be programmed to any value between about 20 volts and about 35 volts, Vh_{reg} may be programmed to any value between about 15 volts and about 28 volts, Vm_{reg} may be programmed to any value between about 8 volts and about 11 volts, and Vₙ may be programmed to any value between about −8 volts and about −20 volts.

In some embodiments, the register 150 may be hard-wired with values for reference voltages. For example, if the multi-voltage converter is intended to be used only for a particular application (such as biasing PIN diode switches), then the register may be hard-wired at manufacture for that application. This would eliminate the need for a customer to program the register for the desired application.

In some implementations, output voltages Vₕ, Vₙ, Vh_{reg}, and/or Vm_{reg} may be adjusted on-the-fly to obtain better performance of a biased component. For example, a PIN diode switch may provide higher RF isolation between two ports with higher reverse-bias voltages on a diode, so voltages may be increased when high isolation is needed. However, higher output voltages from the converter may cause the boost converter to operate less efficiently. When high RF isolation is not needed, voltages may be decreased to improve voltage conversion efficiency and reduce power consumption.

In some implementations, on-board logic and digital components may operate at supply voltages lower than the supply voltage Vₛ provided to the voltage supply contact Vs. For example, the provided supply voltage Vₛ may be about 5 volts, and the on-board digital logic circuitry may operate at 3.3 volts or as low as 1.8 volts. According to some embodiments, a low-voltage (LV) LDO 110 may be included with the multi-voltage converter 100 on the substrate 105 and within the same package. The LV LDO 110 may receive the same supply voltage Vₛ used for powering the multi-voltage converter 100, and output a lower voltage for digital logic. The output voltage from the LV LDO may be provided to an external contact Vdig for external use and/or monitoring.

In some applications, it may be desirable to activate an external RF component only at certain times. For example, RF TDD transceiver circuitry may include a low-noise amplifier that only needs to be active when RF signals are being received, and that can be deactivated when RF signals are being transmitted. To reduce energy consumption and/or avoid amplifier damage, the low-noise amplifier may be deactivated for a period of time when signal amplification is not needed, and receive an activation or enable signal from the TTL buffer 110 when needed. According to some embodiments, the TTL buffer is configured to produce an enable signal (e.g., a logic hi or lo signal) at an enable contact EN1ₒᵤₜ that indicates the bias driver is activated (e.g., PIN diodes have been biased to switch a TDD system to a receive mode). External detection of the enable signal may then cause activation of a low-noise amplifier in the receive signal path. In some implementations, an enable signal at the enable contact EN1ₒᵤₜ may be used for other purposes in controlling RF components that are used in combination with the multi-voltage converter 100.

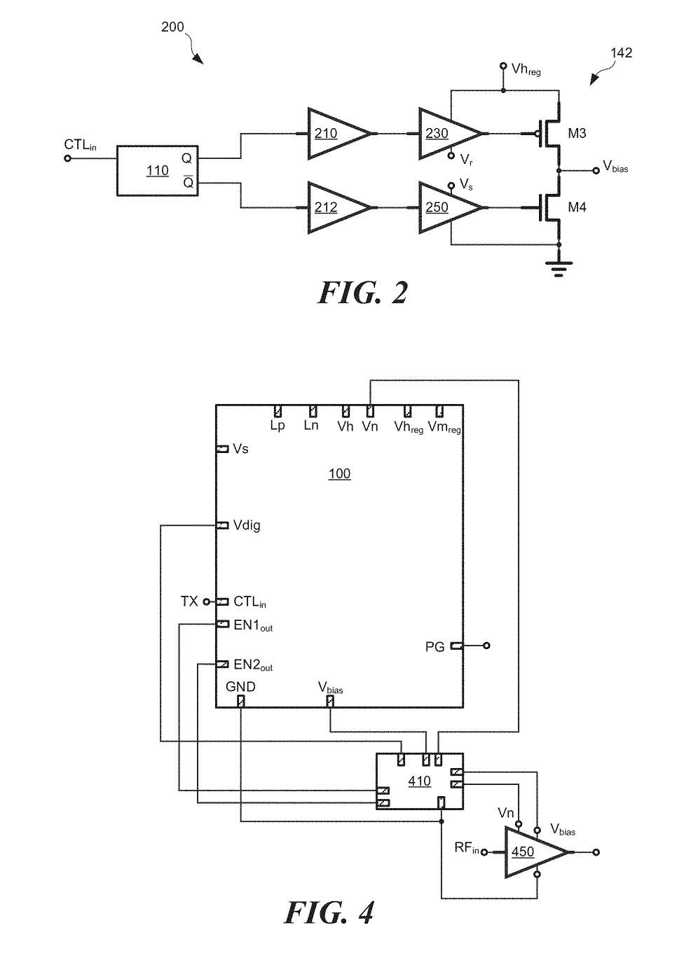

FIG. 2 schematically depicts components of a bias driver 142, according to some embodiments. In this example, the bias driver is arranged to switch an output bias voltage V_{bias} between two levels, approximately Vh_{reg} and approximately ground potential. Alternative bias driver circuits may be used for other implementations, and may be configured to switch the output bias voltage between other voltage levels (e.g., which may include Vm_{reg} and Vn). According to some embodiments, a bias driver may comprise a pair of level shifters 210, 212 configured to receive enable or not-enable signals from the TTL buffer 110. One branch of a bias driver may control a first transistor M3 via a first buffer 230, and a second branch of the bias driver may control a second transistor M4 via a second buffer 250. The second transistor M4 may be of opposite conductivity type than that of the first transistor M3.

In some implementations, the buffers 230, 250 may be low-voltage buffers of the same type (e.g., 5-volt buffers). However, the supply and reference voltages for each buffer may differ. For example, the first buffer 230 may be configured to drive a p-type transistor M3 that switches the high voltage Vh_{reg} onto and off the biasing node V_{bias}. Accordingly, its supply voltage may be Vh_{reg} and its reference voltage Vᵣ may be about 5 volts below Vh_{reg}. The reference voltage Vᵣ may be provided by a suitable voltage reference circuit 115, referring again to FIG. 1. In some cases, the reference voltage Vᵣ and its circuit may be included in reference circuitry 160. A level shifter 210 may shift the voltage level from TTL buffer 110 to a higher value that is suitable for operating the first buffer 230.

The second buffer 250 may be configured to drive an n-type transistor M4 that switches the biasing node to a low voltage or ground potential. The second buffer 250 may receive the supply voltage Vₛ used for powering the multi-voltage converter 100 and receive a reference voltage at ground potential, for example.

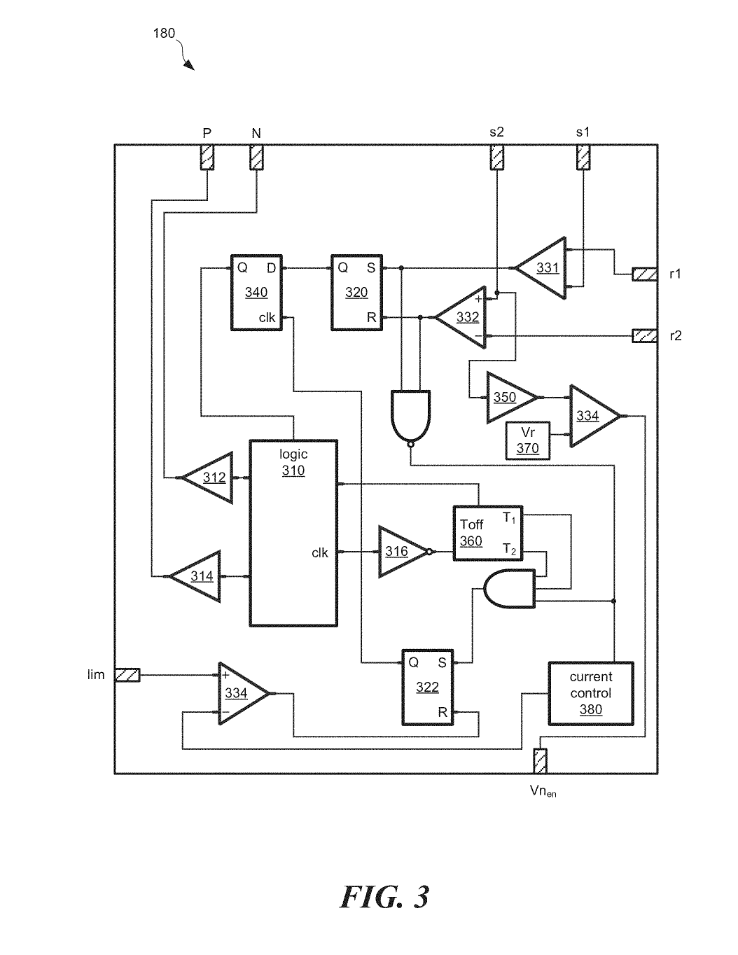

Some components that may be included in some embodiments of the switch control 180 are depicted in FIG. 3. In some implementations, the switch control 180 may utilize current-limit control and combine aspects of pulse width modulation (PWM) and pulse frequency modulation (PFM) to determine when to operate the transistors M1, M2 to drive current through the inductor L1. In PWM, a first comparator 331 senses the high voltage output from the boost converter (appearing across capacitor C1, referring to FIG. 1), and sets a status signal at a first resettable latch 320. A negative-voltage crossing (appearing across capacitor C2) sensed via the negative-voltage contact Vn and compared with a second comparator 332 determines when the first latch 320 is reset. An internal clock circuit, comprising a second latch 322, a clocked flip-flop 340, and a selectable off-period circuit 360 may receive a clock signal from central logic 310 of the switch control 180 and receive inputs from AND gates indicating the voltage status on the boost converter outputs and current level applied to the inductor L1. The internal clock may have a variable period or frequency. According to some embodiments, the central logic 310 may select a first off-period T₁ of the internal clock and drive output buffers 312, 314 (which drive gates of transistors M1, M2) using the first off-period T₁ until the sensed high-voltage reaches a first threshold value. Then the central logic 310 may select a second off-period T₂ at which to alternatingly apply voltage across the inductor L1 until the current in the inductor reaches a first threshold value. Subsequently, the central logic 310 may select the first off-period T₁ for allowing current to dissipate from the inductor L1, and the cycle of applying and dissipating current from the inductor may be repeated using two different off-periods. Circuitry for sensing current in the inductor and comparing against threshold values may include current control circuitry 380 that outputs a reference voltage value to a third comparator 334. The third comparator may receive an input from a current limit contact (labeled “Iₛ” in the drawing) that connects to an end of the inductor L1.

FIG. 4 depicts one example of using a multi-voltage converter 100 to bias an external GaN amplifier 450 for RF communications. A positive voltage Vh_{reg} may be generated by the multi-voltage converter 100 as described above and used to supply power to the GaN amplifier (e.g., to a drain of one or more GaN transistors in the amplifier). In some embodiments, the multi-voltage converter 100 may provide the positive voltage through its controlled biasing contact V_{bias} to a sequencing circuit 410. The positive voltage provided to the sequencing circuit to supply the amplifier may be between approximately 15 volts and approximately 28 volts, in some embodiments. Also, a negative voltage Vₙ may be generated by the multi-voltage converter 100 as described above and used to bias the GaN amplifier's gate prior to and during power-up of the amplifier. The negative voltage may also be provided to the sequencing circuit 410.

In some cases, the sequencing circuit 410 may be used to control the biasing sequence of the amplifier 450. For example, the sequencing circuit may control when the supply voltage Vh_{reg} and the negative voltage Vₙ are provided to the amplifier 450. The sequencer may include logic circuits that assure that the supply voltage is not applied to the amplifier 450 (e.g., to the drain(s) of the amplifier) when there is a DC voltage on the amplifier's gate(s) greater than a predetermined amount (e.g., greater than about −8 volts). In some implementations, the sequencing circuit 410 may further ensure that a negative bias is applied to the gate(s) of the amplifier prior to and during power down. The sequencing circuit may also receive enable signals from the multi-voltage converter 100 that indicate when the high voltage Vh_{reg} and/or the negative voltage Vₙ are available for added protection when biasing the amplifier. Alternatively or additionally, the sequencing circuit 410 may include at least an on-board negative voltage monitor for assuring that the negative voltage is available.

As described above, the RF amplifier may be switched off during operation when not needed to conserve power in some applications. A control signal TX for powering down, and/or powering up the amplifier 450 may be received by the multi-voltage converter 100 at a bias-control contact CTLᵢₙ. Even though the amplifier 450 may be switched on and off during operation by an external control signal, the sequencing circuit 410 can continue its operation normally to assure that the amplifier 450 is powered up and/or powered down properly.

Methods for biasing RF components, such as PIN diodes and/or GaN devices, using the above-described multi-voltage converter may also be implemented. For example, a method for biasing RF components may comprise acts of receiving, at the multi-voltage converter, a first supply voltage, converting, with a boost converter assembled on the substrate, the first supply voltage to a second voltage that is positive and greater than the first voltage, and converting, with the boost converter, the first supply voltage to a negative voltage that is less than the first voltage. A method may further include acts of reducing, with a low-dropout regulator assembled on the substrate, the second voltage to a third voltage, and providing the third voltage and the negative voltage to bias a radio-frequency component. The act of converting may comprise switching two transistors to drive current through a single inductor. The switching may comprise a combination of pulse width modulation and pulse frequency modulation.

In some embodiments, the RF component may comprise a GaN transistor. A method may further include biasing a GaN transistor (e.g., a GaN HEMT) of an amplifier by applying a negative voltage Vₙ from a negative voltage contact to a gate of the GaN transistor, and then applying a high voltage from the HV LDO to a drain of the transistor.

### CONCLUSION

The terms “approximately” and “about” may be used to mean within ±20% of a target value in some embodiments, within ±10% of a target value in some embodiments, within ±5% of a target value in some embodiments, and yet within ±2% of a target value in some embodiments. The terms “approximately” and “about” may include the target value.

The technology described herein may be embodied as a method, of which at least some acts have been described. The acts performed as part of the method may be ordered in any suitable way. Accordingly, embodiments may be constructed in which acts are performed in an order different than described, which may include performing some acts simultaneously, even though described as sequential acts in illustrative embodiments. Additionally, a method may include more acts than those described, in some embodiments, and fewer acts than those described in other embodiments.

Having thus described at least one illustrative embodiment of the invention, various alterations, modifications, and improvements will readily occur to those skilled in the art. Such alterations, modifications, and improvements are intended to be within the spirit and scope of the invention. Accordingly, the foregoing description is by way of example only and is not intended as limiting. The invention is limited only as defined in the following claims and the equivalents thereto.

What is claimed is:

1. A voltage converter comprising:
a substrate on which the voltage converter is assembled;
a supply voltage contact configured to receive electrical power from a power source having a positive voltage;
a boost converter connected to the supply voltage contact and configured to convert a first voltage received from the power source to a second voltage that is greater than the first voltage, to a third voltage that is greater than the first voltage, and to a negative voltage;
a low-dropout regulator configured to convert the second voltage to a fourth voltage; and
a register configured to output a first control signal that sets at least the fourth voltage within a positive voltage range that is greater than zero volts.

2. The voltage converter of claim 1, wherein the boost converter is configured to output up to 80 mA for the fourth voltage and/or the negative voltage.

3. The voltage converter of claim 1, wherein the supply voltage contact is the only contact for receiving power that powers the voltage converter.

4. The voltage converter of claim 1, wherein the register is programmable and is configured to receive a digital signal via a programming contact on the substrate and alter a value of the first control signal responsive to the received digital signal.

5. The voltage converter of claim 4, wherein the register is further configured to output a second control signal that alters the negative voltage within a negative voltage range.

6. The voltage converter of claim 5, wherein the negative voltage range is from approximately −8 volts to approximately −20 volts.

7. The voltage converter of claim 1, wherein the positive voltage range is from approximately 15 volts to approximately 28 volts.

8. The voltage converter of claim 1, wherein the boost converter comprises:
two transistors;
two inductor contacts on the substrate that are connected to the two transistors; and
switching circuitry configured to switch current through an inductor that attaches to the two inductor contacts.

9. The voltage converter of claim 8, wherein an input of the low-dropout regulator is arranged to connect to a cathode of a diode having an anode that connects to the inductor.

10. The voltage converter of claim 1, wherein the first voltage is between approximately 2.5 volts and approximately 7 volts.

11. The voltage converter of claim 1, further comprising a bias driver configured to receive a supply voltage from the low-dropout regulator and switch an output bias voltage between two levels.

12. The voltage converter of claim 11, further comprising a TTL buffer configured to receive commands via a bias-control contact and activate or deactivate the bias driver.

13. The voltage converter of claim 11, wherein the bias driver comprises:
a first transistor having a drain connected to receive an output voltage from the low-dropout regulator;
a first buffer configured to receive power from the low-dropout regulator, to be referenced to a reference voltage that is less than a voltage from the low-dropout regulator and greater than zero volts, and to drive a gate of the first transistor;
a second transistor having a drain connected to a source of the first transistor; and
a second buffer configured to drive a gate of the second transistor.

14. The voltage converter of claim 1, configured to apply the fourth voltage and the negative voltage to a radio-frequency component.

15. The voltage converter of claim 1, wherein the radio-frequency component comprises a gallium-nitride transistor.

16. A method for biasing radio-frequency components with a multi-voltage converter, the method comprising:
receiving, at the multi-voltage converter assembled on a substrate, a first supply voltage;
converting, with a boost converter assembled on the substrate, the first supply voltage to a second voltage that is positive and greater than the first voltage;
converting, with the boost converter, the first supply voltage to a negative voltage that is less than the first voltage;
reducing, with a low-dropout regulator assembled on the substrate, the second voltage to a third voltage; and
providing the third voltage and the negative voltage to bias a radio-frequency component.

17. The method of claim 16, wherein between about 45 mA and 80 mA are provided for the third voltage.

18. The method of claim 16, wherein the first supply voltage is the only supply voltage received by the voltage converter.

19. The method of claim 16, further comprising:
receiving, at a programmable register assembled on the substrate, a digital signal; and
providing, in response to receiving the digital signal, a control signal from the programmable register that alters the third voltage from a first value to a second value within a positive voltage range that is greater than zero volts.

20. The method of claim 16, wherein converting the first supply voltage to the second voltage and converting the first supply voltage to the negative voltage comprises switching two transistors to drive current through a single inductor.

21. The method of claim 20, wherein the switching comprises a combination of pulse width modulation and pulse frequency modulation.

22. The method of claim 16, wherein the first supply voltage is between approximately 2.5 volts and approximately 7 volts and the second voltage is between approximately 20 volts and approximately 35 volts.

23. The method of claim 22, wherein the negative voltage is between approximately −8 volts and approximately −20 volts.

24. The method of claim 16, further comprising:
providing the third voltage and the negative voltage to a sequencing circuit; and
controlling, with the sequencing circuit, the application of the third voltage and the negative voltage to the radio-frequency component.

25. The method of claim 24, wherein the radio-frequency component comprises a gallium-nitride transistor.
